(19) United States
(12) Patent Application Publication
(10) Pub. No.: US 2013/0313605 A1
(43) Pub. Date: Nov. 28, 2013

(54) ELECTRODE CONTACT STRUCTURE OF LIGHT-EMITTING DIODE

(71) Applicants: Li-Ping Chou, Taichung City (TW); Fu-Bang Chen, Taichung City (TW); Chih-Sung Chang, Taichung City (TW)

(72) Inventors: Li-Ping Chou, Taichung City (TW); Fu-Bang Chen, Taichung City (TW); Chih-Sung Chang, Taichung City (TW)

(21) Appl. No.: 13/478,318

(22) Filed: May 23, 2012

(51) Int. Cl. H01L 33/40; H01L 33/22

(52) U.S. Cl. 257/99; 257/E33.062

(57) ABSTRACT

A light-emitting diode (LED) electrode contact structure for an LED is provided. The LED includes a plurality of N-type electrodes, an N-type semiconductor layer, a light-emitting layer, a P-type semiconductor layer, a mirror layer, a buffer layer, a binding layer, a permanent substrate and a P-type electrode that are stacked in sequence. The N-type semiconductor layer has an irregular surface and a plurality of contact platforms. The contact platforms are formed and distributed on the N-type semiconductor layer in a patterned arrangement, and the irregular surface is formed at areas on the N-type semiconductor layer without the contact platforms. The N-type electrodes are respectively formed on the contact platforms. Through flat interfaces provided by the contact platforms, voids are not generated when the N-type electrodes are formed on the contact platforms. Therefore, satisfactory electrical contact is ensured to thereby increase light emitting efficiency.

### FIELD OF THE INVENTION

The present invention relates to a light-emitting diode (LED), and particularly to an electrode contact structure of an LED.

### BACKGROUND OF THE INVENTION

A light-emitting diode (LED), offering advantages of being compact in size and power-saving, prevails in applications including illuminations, traffic lights and commercial signs. An LED is principally formed by a semiconductor material with multiple stacked epitaxial layers. For example, a blue-light LED is mainly consisted of gallium nitride-based (GaN-based) epitaxial thin films.

Referring to FIGS. 1A and 1B, a conventional vertical

LED includes a sandwich structure formed by an N-type semiconductor layer 1, a light-emitting layer 2 and a P-type semiconductor layer 3. Below the P-type semiconductor layer 3, a mirror layer 4, a buffer layer 5, a binding layer 6, a silicon substrate 7 and a P-type electrode 8 are formed in sequence. A surface of the N-type semiconductor layer 1 is processed by a roughening treatment for increasing light extraction. An N-type electrode 9 is further provided. By applying a voltage to the N-type electrode 9 and the P-type electrode 8, the N-type semiconductor layer 1 is enabled to provide electrons and the P-type semiconductor layer 3 is enabled to provide holes. Light is produced by the electrons and holes combining at the light-emitting layer 2.

As previously stated, to increase light extraction, the surface of the N-type semiconductor layer 1 is processed by a roughening treatment to form an irregular surface 1A, upon which the N-type electrode 9 is directly formed. Further, the N-type electrode 9 is generally formed by a thin-film process such as sputtering or evaporation. As a result, as shown in FIG. 1B, voids 1B are formed at blind corners of the irregular surface 1A. The voids 1B not only cause poor contact that increases contact impedance, but are also likely to generate dangling bonds in molecules that limit carriers when manufacturing the irregular surface 1A. Consequently, the overall light emitting efficiency is degraded.

### SUMMARY OF THE INVENTION

Therefore, the primary object of the present invention is to provide a light-emitting diode (LED) electrode contact structure for an LED to prevent poor contact caused by voids generated between electrodes and a semiconductor structure to thus increase light emitting efficiency.

An LED electrode contact structure for an LED is provided according to an embodiment of the present invention. The LED comprises a plurality of N-type electrodes, an N-type semiconductor layer, a light-emitting layer, a P-type semiconductor layer, a mirror layer, a buffer layer, a binding layer, a permanent substrate and a P-type electrode that are stacked in sequence. Further, an irregular surface is formed on the N-type semiconductor layer.

The present invention is characterized in that the N-type semiconductor layer includes a plurality of contact platforms which are formed and distributed thereon in a patterned arrangement. On the N-type semiconductor layer, the irregular surface is formed at areas without the contact platforms. Further, the N-type electrodes are respectively formed on the contact platforms.

Accordingly, in the present invention, the N-type electrodes are respectively formed on the contact platforms. Through flat interfaces provided by the contact platforms, voids are not generated when the N-type electrodes are formed by a thin-film process. Therefore, the structure of the present invention ensures satisfactory electrical contact between the N-type electrodes and the contact platforms, so that dangling bonds in molecules that limit carriers when manufacturing the irregular surface are prevented to thereby increase the light emitting efficiency.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1A is a schematic diagram of a conventional LED.

FIG. 1B depicts voids in a conventional LED.

FIG. 2 is a schematic diagram of an LED structure according to one embodiment of the present invention.

FIGS. 3A to 3C are schematic diagrams of a manufacturing process of an LED structure according to one embodiment of the present invention.

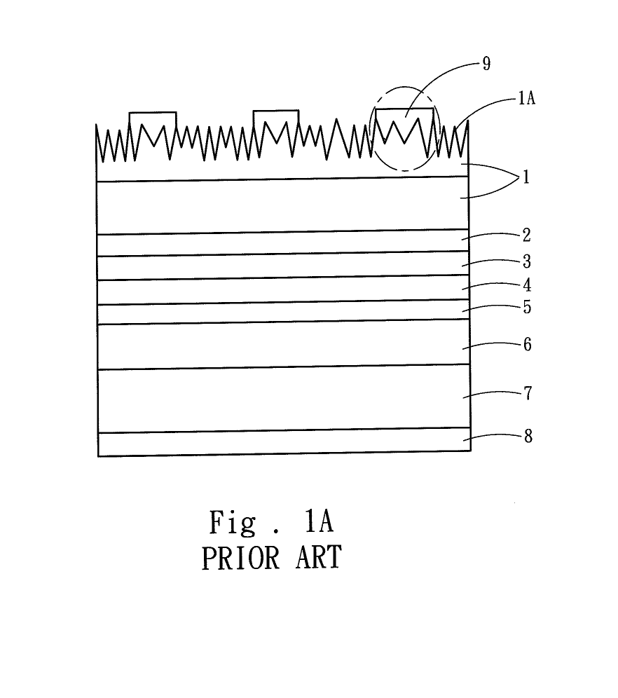

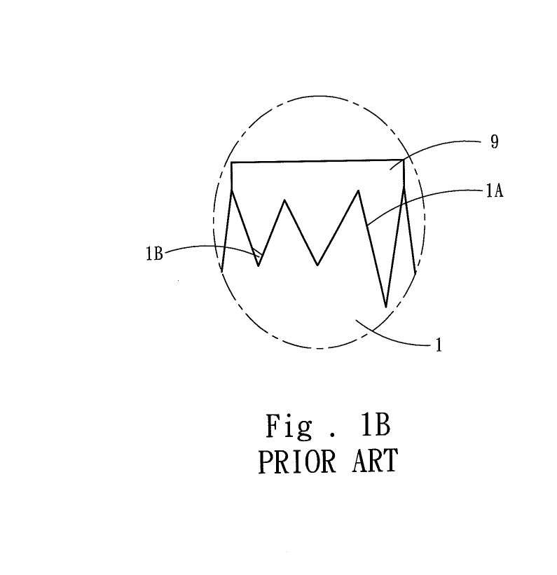

### DETAILED DESCRIPTION OF THE PREFERRED EMBODIMENTS

In the following detailed description, for purposes of explanation, numerous specific details are set forth in order to provide a thorough understanding of the disclosed embodiments. It will be apparent, however, that the embodiments are for exemplary examples for illustrating the prevent invention and are not to be construed as limiting the present invention thereto.

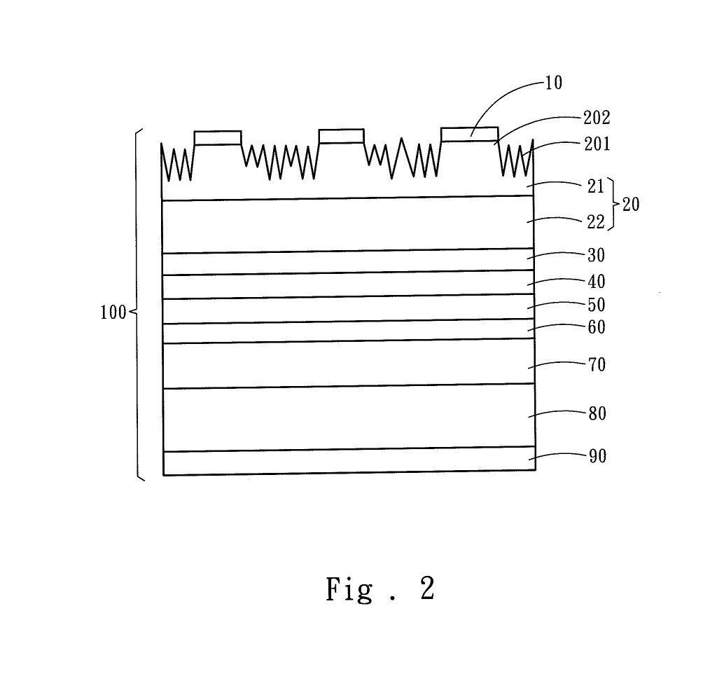

FIG. 2 shows a schematic diagram of an LED electrode structure for an LED according to one embodiment of the present invention. An LED 100 comprises a plurality of N-type electrodes 10, an N-type semiconductor layer 20, a light-emitting layer 30, a P-type semiconductor layer 40, a mirror layer 50, a buffer layer 60, a binding layer 70, a permanent substrate 80 and a P-type electrode 90 that are stacked in sequence. An irregular surface 201 is formed on the N-type semiconductor layer 20.

The N-type semiconductor layer 20 integrally forms a plurality of contact platforms 202. The contact platforms 202 are formed and distributed on the N-type semiconductor layer 20 in a patterned arrangement. On the N-type semiconductor layer 20, the irregular surface 201 is formed at areas without the contact platforms 202. The N-type electrodes 10 are respectively formed on the contact platforms 202.

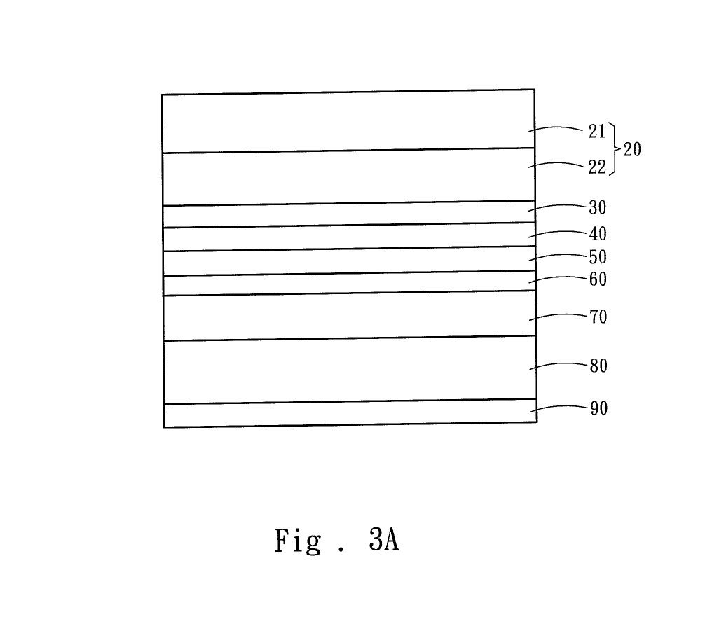

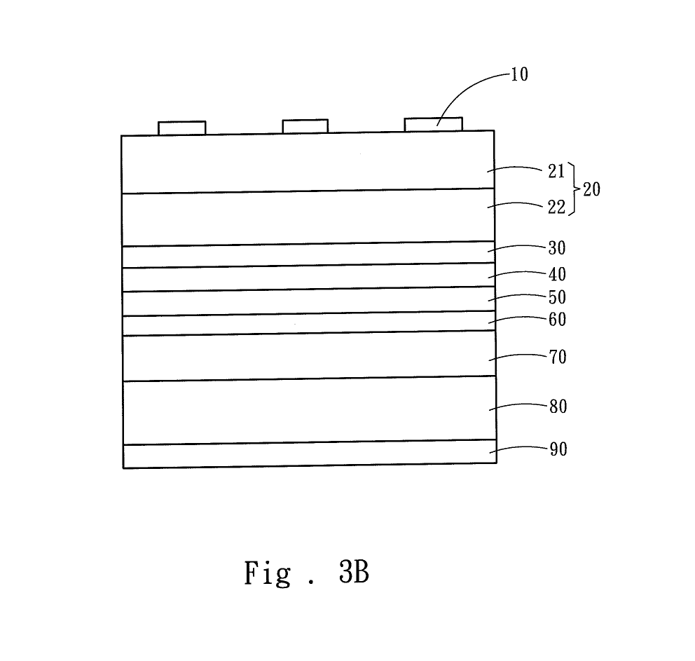

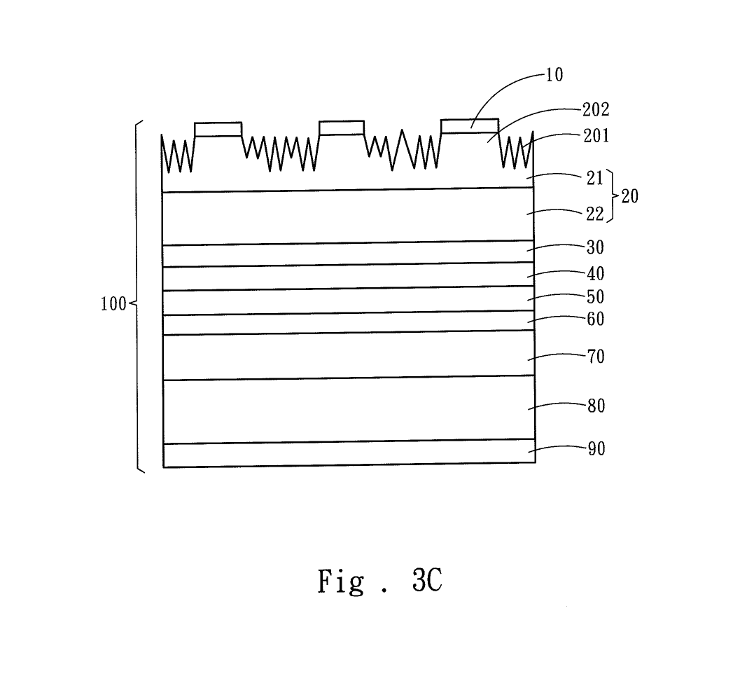

FIGS. 3A to 3C show schematic diagrams of a manufacturing process according to one embodiment of the present invention.

Referring to FIG. 3A, an N-type semiconductor layer 20, a light-emitting layer 30, a P-type semiconductor layer 40, a mirror layer 50, a buffer layer 60, a binding layer 70, a permanent substrate 80 and a P-type electrode 90 are sequentially stacked. The N-type semiconductor layer 20 comprises a first N-type semiconductor layer 21 and a second N-type semiconductor layer 22. The buffer layer 60 is made of a material selected from the group consisting of titanium, tungsten, platinum, nickel, aluminum and chromium. The binding layer 70 is made of a material selected from the group consisting of a gold tin alloy, a gold indium alloy and a gold lead alloy. The permanent substrate 80 is selected from the group consisting of a silicon substrate, a copper substrate, a copper tungsten substrate, an aluminum nitride substrate and a titanium nitride substrate. The mirror layer 50 is made of a material selected from the group consisting of aluminum, nickel, silver and titanium.

Referring to FIG. 3B, by a thin-film process such as evaporation, a plurality of patterned N-type electrodes 10 are formed on the N-type semiconductor layer 20 (i.e., the first N-type semiconductor layer 21).

Referring to FIG. 3C, by a roughening process, an irregular surface 201 is formed on the N-type semiconductor layer 20 (i.e., the first N-type semiconductor layer 21), and the irregular surface 201 may also be formed by a physical approach such as plasma impact. Further, through shielding provided by the N-type electrodes 10, the plurality of contact platforms 202 are formed on the N-type semiconductor layer 20 (i.e., the first N-type semiconductor layer 21), thereby completing the structure of the present invention.

With the above description, it is demonstrated that the N-type electrodes 10 are respectively formed on the contact platforms 202 to be in contact with the N-type semiconductor layer 20. Through flat interfaces provided by the contact platforms 202, voids are not generated when the N-type electrodes 10 are formed by the thin-film process. Therefore, the structure of the present invention ensures satisfactory electrical contact between the N-type electrodes 10 and the contact platforms 202, so that dangling bonds in molecules that limit carriers when manufacturing the irregular surface 201 are prevented to thereby increase the light emitting efficiency.

While the preferred embodiments of the invention have been set forth for the purpose of disclosure, modifications of the disclosed embodiments of the invention as well as other embodiments thereof may occur to those skilled in the art. Accordingly, the appended claims are intended to cover all embodiments which do not depart from the spirit and scope of the invention.

What is claimed is:

1. A light-emitting diode (LED) electrode contact structure for an LED, the LED comprising a plurality of N-type electrodes, an N-type semiconductor layer, a light-emitting layer, a P-type semiconductor layer, a mirror layer, a buffer layer, a binding layer, a permanent substrate and a P-type electrode that are stacked in sequence, the N-type semiconductor layer including an irregular surface; the LED electrode contact structure being characterized in that:
the N-type semiconductor layer includes a plurality of contact platforms which are formed and distributed thereon in a patterned arrangement, the irregular surface is formed at areas on the N-type semiconductor layer without the plurality of contact platforms, and the plurality of N-type electrodes are respectively formed on the plurality of contact platforms.

2. The LED electrode contact structure of claim 1, wherein the N-type semiconductor layer comprises a first N-type semiconductor layer and a second N-type semiconductor layer, and the plurality of contact platforms are formed on the first N-type semiconductor layer.

3. The LED electrode contact structure of claim 1, wherein the buffer layer is made of a material selected from the group consisting of titanium, tungsten, platinum, nickel, aluminum and chromium.

4. The LED electrode contact structure of claim 1, wherein the binding layer is made of a material selected from the group consisting of a gold tin alloy, a gold indium alloy and a gold lead alloy.

5. The LED electrode contact structure of claim 1, wherein the permanent substrate is selected from the group consisting of a silicon substrate, a copper substrate, a copper tungsten substrate, an aluminum nitride substrate and a titanium nitride substrate.

6. The LED electrode contact structure of claim 1, wherein the mirror layer is made of a material selected from the group consisting of aluminum, nickel, silver and titanium.
